(19) United States
(12) Patent Application Publication
(10) Pub. No.: US 2013/0256756 A1
(43) Pub. Date: Oct. 3, 2013

(54) INTEGRATED CIRCUIT HAVING A STAGGERED HETEROJUNCTION BIPOLAR TRANSISTOR ARRAY

(71) Applicant: Yun Wei, Gilbert, AZ (US)

(72) Inventor: Yun Wei, Gilbert, AZ (US)

(73) Assignee: FREESCALE SEMICONDUCTOR, INC., Austin, TX (US)

(21) Appl. No.: 13/431,506

(22) Filed: Mar. 27, 2012

(51) Int. Cl. H01L 27/082; H01L 29/737

(52) U.S. Cl. 257/197; 257/E27.053; 257/E29.173; 257/E29.188

(57) ABSTRACT

An integrated circuit is provided. The integrated circuit may include, but is not limited to, a plurality of heterojunction bipolar transistors, wherein each heterojunction bipolar transistor is staggered with respect to any adjacent heterojunction bipolar transistor. The plurality of heterojunction bipolar transistors may be arranged in a column, wherein each heterojunction bipolar transistor is staggered in the column with respect to any adjacent heterojunction bipolar transistor in the column in a first direction and a second direction, wherein the second direction is substantially orthogonal to the first direction.

### TECHNICAL FIELD

The following relates to circuits, and more particularly to monolithic microwave integrated circuits.

### BACKGROUND

Monolithic microwave integrated circuits are a type of integrated circuit (IC) device that operates at microwave frequencies (300 MHz to 300 GHz). These devices typically perform functions such as microwave mixing, power amplification, low noise amplification, and high frequency switching. Monolithic microwave integrated circuits often include an array of heterojunction bipolar transistors used to amplify power for radio frequency applications.

### DESCRIPTION OF THE DRAWING FIGURES

Exemplary embodiments will hereinafter be described in conjunction with the following drawing figures, wherein like numerals denote like elements.

FIG. 1 illustrates an exemplary layout for a monolithic microwave integrated circuit, in accordance with an embodiment;

FIG. 2 illustrates an exemplary heterojunction bipolar transistor, in accordance with an embodiment;

FIG. 3 is a side view of the heterojunction bipolar transistor illustrated in FIG. 2, in accordance with an embodiment;

FIG. 4 illustrates an exemplary circuit level layout of the microwave integrated circuit illustrated in FIG. 1, in accordance with an embodiment;

FIG. 5 illustrates another exemplary circuit level layout for the microwave integrated circuit illustrated in FIG. 1, in accordance with an embodiment;

FIG. 6 illustrates another exemplary heterojunction bipolar transistor, in accordance with an embodiment; and

FIG. 7 illustrates yet another exemplary heterojunction bipolar transistor, in accordance with an embodiment.

### DETAILED DESCRIPTION

According to various exemplary embodiments, an integrated circuit is provided. The integrated circuit includes at least one column of heterojunction bipolar transistors. Each heterojunction bipolar transistor in each column is arranged on the monolithic microwave integrated circuit in a staggered fashion. By staggering each heterojunction bipolar transistor in the column, the amount of thermal coupling between each heterojunction bipolar transistor is reduced, stabilizing the output of the integrated circuit by improving the linearity of the output of each heterojunction bipolar transistor and improving the overall reliability and lifespan of the monolithic microwave integrated circuit.

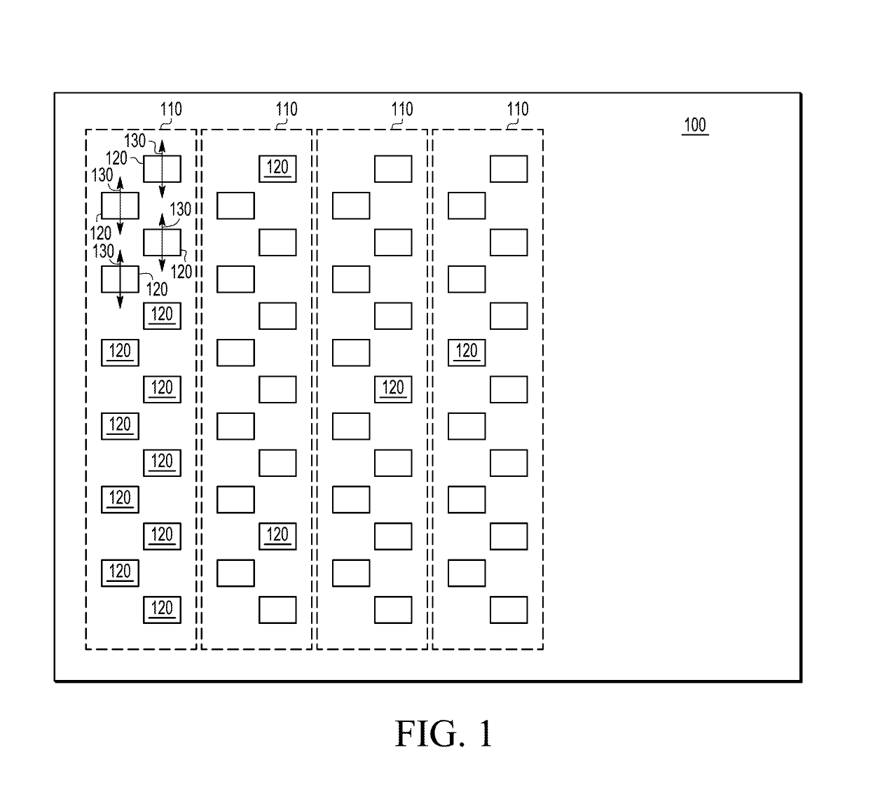

FIG. 1 illustrates an exemplary layout for an integrated circuit (IC) 100, in accordance with an embodiment. The IC 100 may be any type of integrated circuit. In one embodiment, for example, the IC 100 may be a monolithic microwave integrated circuit (MMIC). In another embodiment, for example, the HBTs may be used in a power transistor. The difference between a power transistor and an MMIC is that the power transistor doesn't have lossless passive components such as capacitors and inductors. In yet another embodiment, for example, the HBT 120 may be used as radio frequency (RF) or millimeter wave power amplifiers. The HBTs 120 in each column 110 are arranged in a staggered fashion, such that no two HBTs 120 in each column are adjacent to each other in a first direction and a second direction substantially orthogonal to the first direction. Furthermore, the columns 110 can be arranged such that no two HBTs 120 are adjacent to each other between the columns 110, as illustrated in FIG. 1.

Each HBT 120, when active, emits heat, illustrated by arrows 130. The amount of current that flows through a HBT 120 is proportional to the temperature of the HBT 120. In other words, when an HBT 120 is heated, the HBT 120 allows more current to flow from a collector to an emitter even though the voltage input to the HBT 120 stays the same. Furthermore, when more current is flowing through an HBT 120, the amount of heat produced by the HBT 120 is increased. Accordingly, if any two HBTs are arranged in linear fashion with respect to one another, in other words, separated by only in a single direction, the HBTs will increase the currently flowing in the neighboring HBT. If, for example, groups of HBTs are arranged linearly, the amount of current flowing through the central HBTs (i.e., those surrounded by HBTs on both sides) will be greater than the amount of current flowing through edge HBTs. Accordingly, by staggering each HBT 120 in the column 110, the amount of thermal coupling between each HBT 120 is reduced, stabilizing the output of the IC 100 by improving the linearity of the output of each HBT 120 and improving the overall reliability and lifespan of the IC 100. While FIG. 1 illustrates each column 110 as having two columns of HBTs 120, each column 110 may have any number of columns of HBTs 120.

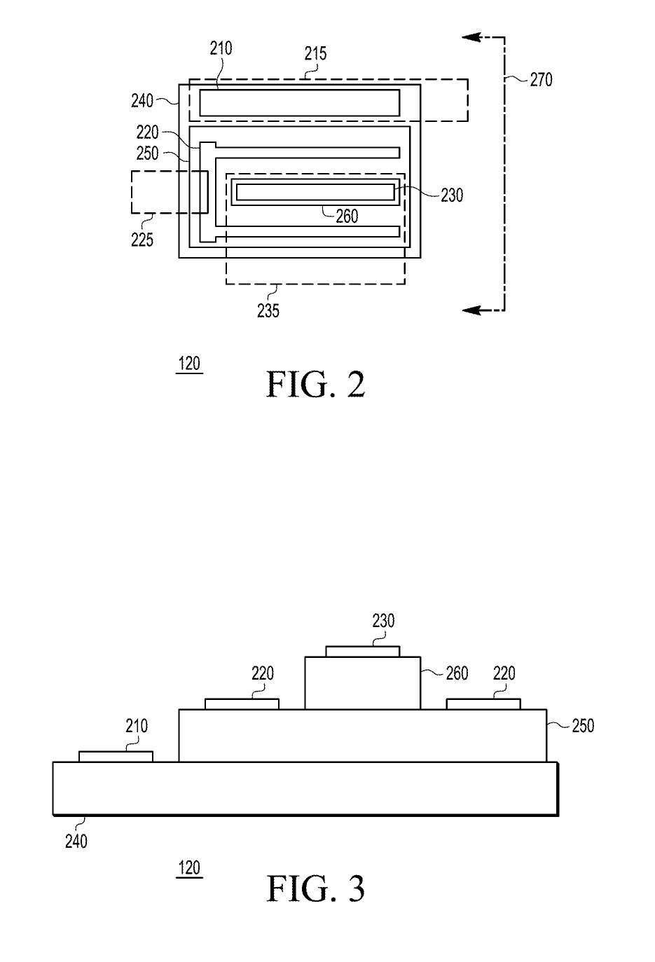

FIG. 2 illustrates an exemplary HBT 120, in accordance with an embodiment. HBTs are a type of bipolar junction transistor (BJT) which uses differing semiconductor materials for the emitter and base regions, creating a heterojunction. The HBT improves on the BJT in that it can handle signals of very high frequencies.

In accordance with one embodiment, the HBT 120 may be a single collector HBT. The HBT 120 includes a collector contact 210, a base contact 220, and an emitter contact 230. The collector contact 210 is disposed on a first substrate region 240. The collector contact 210 may be coupled to a collector interconnect 215. As discussed in further detail below, the collector contact 210 for multiple HBTs 120 may be connected to a common collector bias signal. In the embodiment illustrated in FIG. 1, the base contact 220 is substantially “U” shaped and may be disposed in a single piece on a second substrate region 250. The base contact 220 may be coupled to a base interconnect 225 to connect the base to a base bias signal, as discussed in further detail below. The emitter contact 230 is disposed on a third substrate region 260. In one embodiment, for example, the emitter contact 230 may be coupled to an emitter interconnect trace 235 for connecting the emitter of the HBT to a ballasting resistor, as discussed in further detail below.

HBTs may be fabricated based on semiconductor materials in the form of stack epitaxial layers. The layers may be intentionally doped to n-type or p-type. The doping density can be varied for different purposes. Chemical etch techniques may be used in HBT process to expose the specific layer where a metal-semiconductor ohmic contact needs to be formed. A mesa structure can be formed after chemical etch allowing each transistor to be isolated from each other. The first processed structure may be an emitter mesa. The emitter-metal contact may be formed by depositing a stack metal before or after the emitter mesa etching process. Then a base metal deposition forms the base-metal contact. Using a photo resist mask, two subsequent selective chemical etches can be used to form base and collector mesas. A heavily doped (n+) sub-collector can then be exposed. An ion implant process may be used to isolate a transistor at this layer. After the isolation process, a third stack metal can be deposited on the sub-collector layer to form the collector-metal contact. A high temperature annealing process may then be performed to achieve a metal-semiconductor ohmic alloy. Then a dielectric may be deposited to act as a passivation process to encapsulate the exposed semiconductor material.

FIG. 3 is a side view of the HBT 120 illustrated in FIG. 2 in the direction of arrow 270. As seen in FIG. 2, the collector contact 210 is disposed on a first layer 240, the base contact 220 is disposed on a second layer 250, which is disposed on the first layer 240, and the emitter contact 230 is disposed on a third layer 260, which is disposed on the second layer 250. In one embodiment, for example, the first layer 240 may be n-type collector composed of III-V compound semiconductor, such as GaAs and InP. The second layer 250 may be a p-type base composed of III-V compound semiconductor, such as GaAs and InGaAs. The third layer 260 may be n-type emitter composed of III-V compound semiconductor, such as InGaP, AlGaAs, InP or any other suitable material, but may have heavier doping density than the first layer 240. Because the semiconductor material of the third layer 260 has a wider energy band gap than the second layer 250 semiconductor material, a hetero p-n junction is formed at their interface. Depending on the layer material and type of doping, a variety of stack metal could be used to form semiconductor-metal ohmic contacts 210, 220 and 230.).

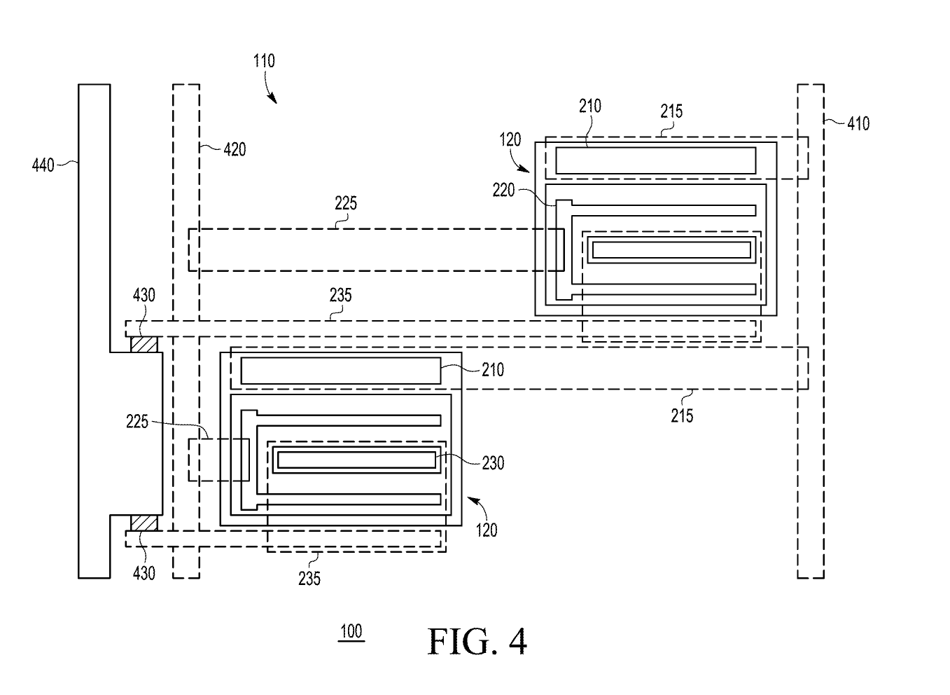

FIG. 4 illustrates an exemplary circuit level layout the IC 100 illustrated in FIG. 1, in accordance with an embodiment. As discussed above, the IC 100 includes a column 110 of HBT 120. FIG. 4 illustrates two HBTs 120 in one column 110. As discussed above, the HBTs 120 are staggered with respect with one another to reduce thermal coupling between the HBTs 120. Furthermore, each HBT 120 only includes one collector contact 210, which allows for the HBTs to be placed closer together in the vertical direction illustrated in FIG. 4, while still maintaining enough separation to reduce thermal coupling since the HBTs 120 are also separated in the horizontal direction as illustrated in FIG. 4. The collector contact 210 for each HBT 120 in each column is ohmically coupled to a common collector bias trace 410 via their respective collector interconnect traces 215. In one embodiment, for example, the common collector bias trace and 410 and collector interconnect traces 215 may be deposited in one piece. The collector contact 210 may be deposited separately since its metal stack may be different from the common collector bias trace and 410 and collector interconnect traces 215. In one embodiment, for example, the common collector bias trace is the radio frequency output of a IC. The base contact 220 for each HBT 120 in the column 110 is coupled to a common base biasing trace 420 via their respective base interconnect traces 225. The common base bias trace 420 may, for example, receive an input signal which causes a current to flow through the HBT 120. The emitter contact 230 is coupled to a ballasting resistor 430 via the emitter interconnect trace 235. The ballasting resistor 430 is then coupled to a ground trace 440. The ballasting resistor 430 limits the amount of current that can flow through the HBT 120. Because the ballasting resistor 430 is coupled to the emitter of the HBT 120, rather than the base of the HBT 120, the resistance of the ballasting resistor 430-can be reduced.

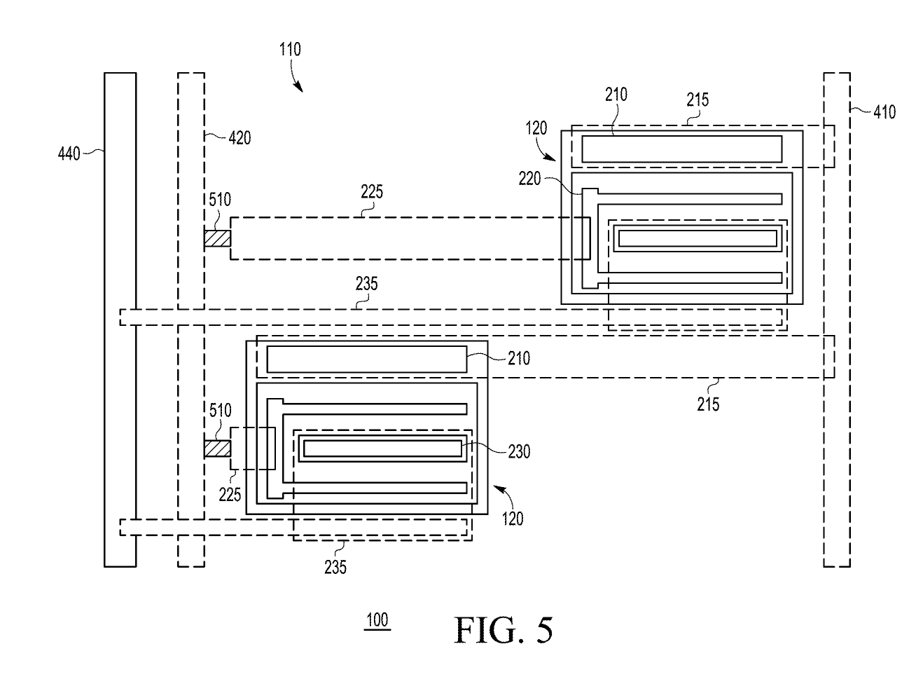

FIG. 5 illustrates another exemplary circuit level layout for the IC 100 illustrated in FIG. 1, in accordance with an embodiment. As with FIG. 4, FIG. 5 illustrates two HBTs 120 in one column 110. As discussed above, the HBTs 120 are staggered with respect with one another to reduce thermal coupling between the HBTs 120. Furthermore, each HBT 120 only includes one collector contact 210, which allows the HBTs to be placed closer together, while still maintaining enough separation to minimize thermal coupling. The collector contact 210 for each HBT 120 is ohmically coupled to a common collector bias trace 410 via their respective collector interconnect traces 215. In one embodiment, for example, the collector bias trace is the radio frequency amplifier output for the IC 100. The base contact 220 for each HBT 120 in the column 110 is coupled to a ballasting resistor 510 via their respective base interconnect traces 225. The ballasting resistor 510 is also coupled to a common base bias trace 420 which may, for example, receive an input signal which causes a current to flow through the HBT 120. The emitter contact 230 for each HBT 120 is coupled to a ground trace 520 via their respective emitter traces 235. The ballasting resistor 510 limits the amount of current that can flow through the HBT 120. However, because the ballasting resistor 510 is coupled to the base of the HBT 120, rather than the emitter of the HBT 120 as illustrated in FIG. 4, the resistance of the ballasting resistor 510 is larger than the ballasting resistor 430 illustrated in FIG. 4. A capacitor (not illustrated) in parallel to the ballasting resistor is usually needed providing a low impedance RF signal path, which will increase the footprint of the array of HBTs on the IC 100 but helps to reduce signal loss.

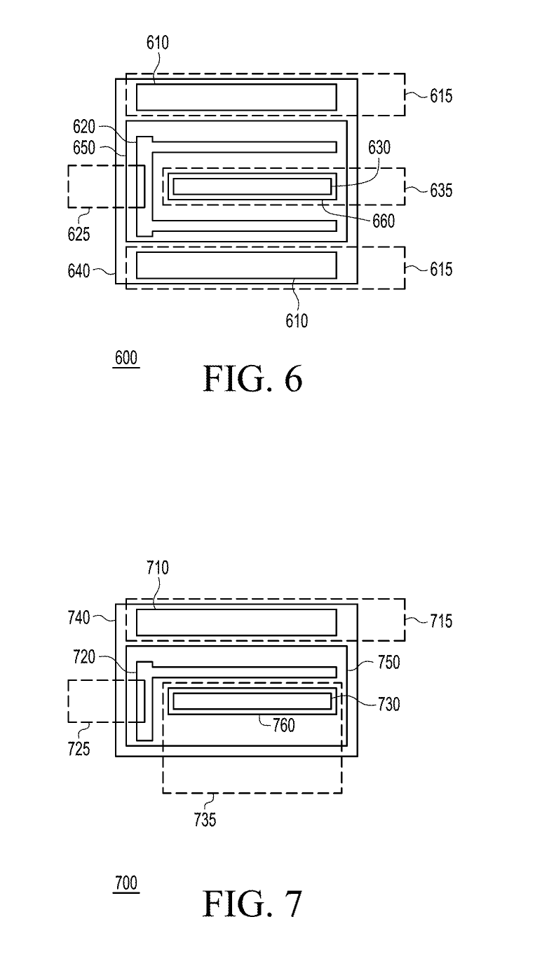

FIG. 6 illustrates another exemplary HBT 600, in accordance with an embodiment. The HBT 600 is a duel collector contact HBT. The HBT 600 includes two collector contacts 610, a base contact 620, and an emitter contact 630. The collector contacts 610 are disposed on a first layer 640. The collector contacts 610 may be coupled to a collector interconnect 615. The collector contacts 610 for multiple HBTs 600 may be connected to a common collector bias signal in a similar fashion as the collector contacts 210 illustrated in FIG. 4 or 5. In the embodiment illustrated in FIG. 6, the base contact 620 is substantially “U” shaped and is disposed on a second layer 650. The based contact 620 may be coupled to a base interconnect 625 to connect the base to a base bias signal, as discussed above. The emitter contact 630 is disposed on a third layer 660. The emitter contact 630 may be coupled to an emitter interconnect 635 for connecting the emitter of the HBT 600 to a ballasting resistor, as discussed in FIG. 4, or to ground, as discussed in FIG. 5. By using a duel collector HBT 600, the spacing between the HBTs when placed in an array (as illustrated in FIG. 1) is increased, further reducing the thermal coupling between the HBTs and improving the performance of the IC. However, correspondingly, the footprint of the HBT array is increased by approximately twenty-five percent to accommodate for the extra collector contacts.

FIG. 7 illustrates yet another exemplary HBT 700 in accordance with an embodiment. The HBT 700 is a single collector HBT having a shrinking base contact. The HBT 700 includes single collector contact 710 a shrinking base contact 720, and an emitter contact 730. The collector contact 710 is disposed on a first layer 740. The collector contact 710 may be coupled to a collector interconnect 715. The collector contacts 710 for multiple HBTs 700 may be connected to a common collector bias signal in a similar fashion as the collector contacts 210 illustrated in FIG. 4 or 5. In the embodiment illustrated in FIG. 7, the base contact 720 is substantially “L” shaped and is disposed on a second layer 750. The based contact 720 may be coupled to a base interconnect 725 to connect the base to a base bias signal, as discussed above. The emitter contact 730 is disposed on a third layer 760. The emitter contact 730 may be coupled to an emitter interconnect 735 for connecting the emitter of the HBT 700 to a ballasting resistor, as discussed in FIG. 4, or to ground, as discussed in FIG. 5. The footprint of the single collector and shrinking base HBT 700 is further decreased compared to the single collector HBT 120 illustrated in FIG. 2. The parasitic capacitance between the collector and base is also decreased and therefore the device can operate at even higher frequency than HBT 120 and HBT 600. By using single collector and shrinking base HBT 700 the spacing between the HBTs when placed in an array (as illustrated in FIG. 1) can be further decreased and therefore the transistor array can be more compact while still maintaining enough separation to reduce thermal coupling.

In one embodiment, for example, an integrated circuit is provided. The integrated circuit may include, but is not limited to, a plurality of heterojunction bipolar transistors, wherein each heterojunction bipolar transistor is staggered with respect to any adjacent heterojunction bipolar transistor of the plurality of heterojunction bipolar transistors. Each heterojunction bipolar transistor may be staggered with respect to any adjacent heterojunction bipolar transistor in a first direction and a second direction, wherein the second direction is substantially orthogonal to the first direction. The plurality of heterojunction bipolar transistors may be arranged in a column, and each heterojunction bipolar transistor may be staggered in the column with respect to any adjacent heterojunction bipolar transistor in the column in a first direction and a second direction, wherein the second direction is substantially orthogonal to the first direction. The plurality of heterojunction bipolar transistors may arranged in a plurality of columns, and each heterojunction bipolar transistor may be staggered in its column with respect to any adjacent heterojunction bipolar transistor in its column in a first direction and a second direction, wherein the second direction is substantially orthogonal to the first direction, and each heterojunction bipolar transistor may be staggered with respect to adjacent heterojunction bipolar transistor in other columns in the first direction and the second direction. Each heterojunction bipolar transistor may include, but is not limited to, a single collector contact disposed on a first layer, a base contact disposed on a second layer, the second layer being disposed on the first layer, and an emitter contact disposed on a third layer, the third layer being disposed on the second layer. Each heterojunction bipolar transistor may further include a second collector contact disposed on the first layer. The integrated circuit may further include a plurality of ballasting resistors, wherein each ballasting resistor may be coupled to the emitter contact of a different heterojunction bipolar transistor. Each ballasting may be coupled between the emitter contact of the different heterojunction bipolar transistor and ground. Further, each base contact in each column of heterojunction bipolar transistors may be coupled to a common base biasing trace. Each collector contact in each column of heterojunction bipolar transistors may be coupled to a common collector biasing trace. In another embodiment, for example, the integrated circuit may further include a plurality of ballasting resistors, wherein each ballasting resistor is coupled to the base contact of a different heterojunction bipolar transistor. Each ballasting resistor in each column of heterojunction bipolar transistors may be coupled between the base contact of the different heterojunction bipolar transistor and a common base biasing trace. Each emitter contact in each column of heterojunction bipolar transistors may be coupled to a ground. Further, each collector contact in each column of heterojunction bipolar transistors may be coupled to a common collector biasing trace. In one embodiment, for example, the base contact may be substantially L shaped. In another embodiment, for example, the base contact may be substantially U shaped

In another embodiment, for example, a heterojunction bipolar transistor is provided. The heterojunction bipolar transistor may include, but is not limited to, a single collector contact disposed on a first layer, a base contact disposed on a second layer, the second layer being disposed on the first layer, and an emitter contact disposed on a third layer, the third substrate being disposed on the second layer. The base contact may substantially L shaped. In another embodiment, for example, the base contact may be substantially U shaped. The heterojunction bipolar transistor may further include a ballasting resistor, wherein the ballasting resistor is coupled to the emitter contact.

The term “exemplary” is used herein to represent one example, instance or illustration that may have any number of alternates. Any implementation described herein as “exemplary” should not necessarily be construed as preferred or advantageous over other implementations.

Although several exemplary embodiments have been presented in the foregoing description, it should be appreciated that a vast number of alternate but equivalent variations exist, and the examples presented herein are not intended to limit the scope, applicability, or configuration of the embodiments in any way. To the contrary, various changes may be made in the function and arrangement of the various features described herein without departing from the scope of the claims and their legal equivalents.

What is claimed is:

1. An integrated circuit, comprising:
a plurality of heterojunction bipolar transistors, wherein each heterojunction bipolar transistor is staggered with respect to any adjacent heterojunction bipolar transistor of the plurality of heterojunction bipolar transistors.

2. The integrated circuit of claim 1, wherein each heterojunction bipolar transistor is staggered with respect to any adjacent heterojunction bipolar transistor in a first direction and a second direction, wherein the second direction is substantially orthogonal to the first direction.

3. The integrated circuit of claim 1, wherein the plurality of heterojunction bipolar transistors are arranged in a column, and each heterojunction bipolar transistor is staggered in the column with respect to any adjacent heterojunction bipolar transistor in the column in a first direction and a second direction, wherein the second direction is substantially orthogonal to the first direction.

4. The integrated circuit of claim 1, wherein the plurality of heterojunction bipolar transistors are arranged in a plurality of columns, and each heterojunction bipolar transistor is staggered in its column with respect to any adjacent heterojunction bipolar transistor in its column in a first direction and a second direction, wherein the second direction is substantially orthogonal to the first direction and each heterojunction bipolar transistor is staggered with respect to adjacent heterojunction bipolar transistor in other columns in the first direction and the second direction.

5. The integrated circuit of claim 1, wherein each heterojunction bipolar transistor comprises:
a single collector contact disposed on a first layer;
a base contact disposed on a second layer, the second layer being disposed on the first layer; and
an emitter contact disposed on a third layer, the third layer being disposed on the second layer.

6. The integrated circuit of claim 5 wherein each heterojunction bipolar transistor further comprises a second collector contact disposed on the first layer.

7. The integrated circuit of claim 5, further comprising a plurality of ballasting resistors, wherein each ballasting resistor is coupled to the emitter contact of a different heterojunction bipolar transistor.

8. The integrated circuit of claim 7, wherein each ballasting resistor is coupled between the emitter contact of the different heterojunction bipolar transistor and ground.

9. The integrated circuit of claim 8, wherein each base contact in each column of heterojunction bipolar transistors is coupled to a common base biasing trace.

10. The integrated circuit of claim 9, wherein each collector contact in each column of heterojunction bipolar transistors is coupled to a common collector biasing trace.

11. The integrated circuit of claim 5, further comprising a plurality of ballasting resistors, wherein each ballasting resistor is coupled to the base contact of a different heterojunction bipolar transistor.

12. The integrated circuit of claim 11, wherein each ballasting resistor in each column of heterojunction bipolar transistors is coupled between the base contact of the different heterojunction bipolar transistor and a common base biasing trace.

13. The integrated circuit of claim 12, wherein each emitter contact in each column of heterojunction bipolar transistors is coupled to a ground.

14. The integrated circuit of claim 13, wherein each collector contact in each column of heterojunction bipolar transistors is coupled to a common collector biasing trace.

15. The integrated circuit of claim 5, wherein the base contact is substantially L shaped.

16. The integrated circuit of claim 5, wherein the base contact is substantially U shaped.

17. A heterojunction bipolar transistor, comprising:
a single collector contact disposed on a first layer;
a base contact disposed on a second layer, the second layer being disposed on the first layer; and
an emitter contact disposed on a third layer, the third substrate being disposed on the second layer.

18. The heterojunction bipolar transistor of claim 17, wherein the base contact is substantially L shaped.

19. The heterojunction bipolar transistor of claim 17, wherein the base contact is substantially U shaped.

20. The heterojunction bipolar transistor of claim 18, further comprising a ballasting resistor, wherein the ballasting resistor is coupled to the emitter contact.
